(19) United States
(12) Patent Application Publication
(10) Pub. No.: US 2024/0429677 A1
(43) Pub. Date: Dec. 26, 2024

(54) LASER DRIVER CIRCUIT FOR MEASURING ELECTROPHORETIC MOBILITY OF A SAMPLE

(71) Applicant: Wyatt Technology, LLC, Goleta, CA (US)

(72) Inventors: David Rahmlow, Goleta, CA (US); Howard Friedenberg, Santa Barbara, CA (US)

(21) Appl. No.: 18/748,239

(22) Filed: Jun. 20, 2024

Related U.S. Application Data
(60) Provisional application No. 63/522,608, filed on Jun. 22, 2023.

(51) Int. Cl. H01S 5/042

(52) U.S. Cl. CPC H01S 5/042

(57) ABSTRACT

The present disclosure describes a laser driver circuit for measuring electrophoretic mobility of a sample. In an exemplary embodiment, the circuit includes a voltage regulator circuit to receive an input voltage and to output a stable output voltage, an operational amplifier electrically coupled to an output of the voltage regulator circuit, a transistor electrically coupled to an output of the operational amplifier and to the output of the voltage regulator circuit, a plurality of resistors electrically coupled to the operational amplifier and to the transistor, a plurality of capacitors electrically coupled to the operational amplifier, to the transistor, and to the plurality of resistors, and where the operational amplifier is to output a voltage to adjust a gate voltage of the transistor such that a drain source resistance of the transistor allows a controlled current to flow to a laser for measuring electrophoretic mobility of a sample.

### RELATED APPLICATION

This application claims the benefit of the earlier filing date of U.S. Provisional Patent Application Ser. No. 63/522,608, filed Jun. 22, 2023 and titled “Laser Driver Circuit for Measuring Electrophoretic Mobility of a Sample,” the entirety of which is incorporated herein by reference.

### BACKGROUND

The present disclosure relates to electrophoretic mobility, and more specifically, to a laser driver circuit for measuring electrophoretic mobility of a sample.

### SUMMARY

The present disclosure describes a laser driver circuit for measuring electrophoretic mobility of a sample. In an exemplary embodiment, the circuit includes (1) a voltage regulator circuit to receive an input voltage and to output a stable output voltage, (2) an operational amplifier electrically coupled to an output of the voltage regulator circuit, (3) a transistor electrically coupled to an output of the operational amplifier and to the output of the voltage regulator circuit, (4) a plurality of resistors electrically coupled to the operational amplifier and to the transistor, (5) a plurality of capacitors electrically coupled to the operational amplifier, to the transistor, and to the plurality of resistors, and (6) where the operational amplifier is to output a voltage to adjust a gate voltage of the transistor such that a drain source resistance of the transistor allows a controlled current to flow to a laser for measuring electrophoretic mobility of a sample.

In an exemplary embodiment, the circuit includes (1) a laser monitor circuit to generate a laser monitor output voltage indicating an amount of optical power being generated by a laser for measuring electrophoretic mobility of a sample, (2) a constant power integrator circuit electrically coupled to an output of the laser monitor circuit and configured to determine an amount of current required to maintain a particular laser optical output power for the laser, and (3) a constant power-constant current selection circuit electrically coupled to an output of the constant power integrator circuit, where the constant power-constant current selection circuit is to output a selected current for a laser current circuit to flow controlled current to the laser.

### BRIEF DESCRIPTION OF THE DRAWINGS

FIG. 1 depicts a prior art circuit.

FIG. 2A depicts a circuit in accordance with an exemplary embodiment.

FIG. 2B depicts a circuit in accordance with an exemplary embodiment.

FIG. 2C depicts a circuit in accordance with an exemplary embodiment.

FIG. 3A depicts a circuit in accordance with an exemplary embodiment.

FIG. 3B depicts a circuit in accordance with an embodiment.

FIG. 3C depicts a circuit in accordance with an embodiment.

FIG. 3D depicts a circuit in accordance with an embodiment.

FIG. 3E depicts a circuit in accordance with an embodiment.

FIG. 3F depicts a circuit in accordance with an embodiment.

FIG. 3G depicts a circuit in accordance with an embodiment.

FIG. 4A depicts a graph in accordance with an embodiment.

FIG. 4B depicts a graph in accordance with an embodiment.

FIG. 4C depicts a graph in accordance with an embodiment.

### DETAILED DESCRIPTION

The present disclosure describes a laser driver circuit for measuring electrophoretic mobility of a sample. In an exemplary embodiment, the circuit includes (1) a voltage regulator circuit to receive an input voltage and to output a stable output voltage, (2) an operational amplifier electrically coupled to an output of the voltage regulator circuit, (3) a transistor electrically coupled to an output of the operational amplifier and to the output of the voltage regulator circuit, (4) a plurality of resistors electrically coupled to the operational amplifier and to the transistor, (5) a plurality of capacitors electrically coupled to the operational amplifier, to the transistor, and to the plurality of resistors, and (6) where the operational amplifier is to output a voltage to adjust a gate voltage of the transistor such that a drain source resistance of the transistor allows a controlled current to flow to a laser for measuring electrophoretic mobility of a sample. In an embodiment, the operational amplifier includes a low noise, precision operational amplifier with a low offset (e.g., a precision operational amp). In an embodiment, the operational amplifier is a low noise, precision operational amplifier with a low offset. In an embodiment, the transistor includes a n-channel MOSFET. In an embodiment, the transistor is a n-channel MOSFET.

In an exemplary embodiment, the circuit includes (1) a laser monitor circuit to generate a laser monitor output voltage indicating an amount of optical power being generated by a laser for measuring electrophoretic mobility of a sample, (2) a constant power integrator circuit electrically coupled to an output of the laser monitor circuit and configured to determine an amount of current required to maintain a particular laser optical output power for the laser, and (3) a constant power-constant current selection circuit electrically coupled to an output of the constant power integrator circuit, where the constant power-constant current selection circuit is to output a selected current for a laser current circuit to flow controlled current to the laser.

In an embodiment, the circuit has little sensitivity to the power supply rail noise that is suppressed by feedback in the operational amplifier. For example, the circuit of the present disclosure could have a noise performance that is substantially better than current technologies. With the circuit, it is easier to implement reliable current limits as compared to the current technologies, by allowing for the direct limiting of the requested current to a desired range. Tin other words, the circuit allows for implementing current limits that are more repeatable than with current technologies. The circuit also could support a wide range of laser currents.

### Definitions

### Particle

A particle may be a constituent of a liquid sample aliquot. Such particles may be molecules of varying types and sizes, nanoparticles, virus like particles, liposomes, emulsions, bacteria, and colloids. These particles may range in size on the order of nanometer to microns.

### Analysis of Macromolecular or Particle Species in Solution

The analysis of macromolecular or particle species in solution may be achieved by preparing a sample in an appropriate solvent and then injecting an aliquot thereof into a separation system such as a liquid chromatography (LC) column or field flow fractionation (FFF) channel where the different species of particles contained within the sample are separated into their various constituencies. Once separated generally based on size, mass, or column affinity, the samples may be subjected to analysis by means of light scattering, refractive index, ultraviolet absorption, electrophoretic mobility, and viscometric response.

### Light Scattering

Light scattering (LS) is a non-invasive technique for characterizing macromolecules and a wide range of particles in solution. The two types of light scattering detection frequently used for the characterization of macromolecules are static light scattering and dynamic light scattering.

### Dynamic Light Scattering

Dynamic light scattering is also known as quasi-elastic light scattering (QELS) and photon correlation spectroscopy (PCS). In a DLS experiment, time-dependent fluctuations in the scattered light signal are measured using a fast photodetector. DLS measurements determine the diffusion coefficient of the molecules or particles, which can in turn be used to calculate their hydrodynamic radius.

### Static Light Scattering

Static light scattering (SLS) includes a variety of techniques, such as single angle light scattering (SALS), dual angle light scattering (DALS), low angle light scattering (LALS), and multi-angle light scattering (MALS). SLS experiments generally involve the measurement of the absolute intensity of the light scattered from a sample in solution that is illuminated by a fine beam of light. Such measurement is often used, for appropriate classes of particles/molecules, to determine the size and structure of the sample molecules or particles, and, when combined with knowledge of the sample concentration, the determination of weight average molar mass. In addition, nonlinearity of the intensity of scattered light as a function of sample concentration may be used to measure interparticle interactions and associations.

### Multi-Angle Light Scattering

Multi-angle light scattering (MALS) is a SLS technique for measuring the light scattered by a sample into a plurality of angles. It is used for determining both the absolute molar mass and the average size of molecules in solution, by detecting how they scatter light. Collimated light from a laser source is most often used, in which case the technique can be referred to as multiangle laser light scattering (MALLS). The “multi-angle” term refers to the detection of scattered light at different discrete angles as measured, for example, by a single detector moved over a range that includes the particular angles selected or an array of detectors fixed at specific angular locations.

A MALS measurement requires a set of ancillary elements. Most important among them is a collimated or focused light beam (usually from a laser source producing a collimated beam of monochromatic light) that illuminates a region of the sample. The beam is generally plane-polarized perpendicular to the plane of measurement, though other polarizations may be used especially when studying anisotropic particles. Another required element is an optical cell to hold the sample being measured. Alternatively, cells incorporating means to permit measurement of flowing samples may be employed. If single-particles scattering properties are to be measured, a means to introduce such particles one-at-a-time through the light beam at a point generally equidistant from the surrounding detectors must be provided.

Although most MALS-based measurements are performed in a plane containing a set of detectors usually equidistantly placed from a centrally located sample through which the illuminating beam passes, three-dimensional versions also have been developed where the detectors lie on the surface of a sphere with the sample controlled to pass through its center where it intersects the path of the incident light beam passing along a diameter of the sphere. The MALS technique generally collects multiplexed data sequentially from the outputs of a set of discrete detectors. The MALS light scattering photometer generally has a plurality of detectors.

Normalizing the signals captured by the photodetectors of a MALS detector at each angle may be necessary because different detectors in the MALS detector (i) may have slightly different quantum efficiencies and different gains, and (ii) may look at different geometrical scattering volumes. Without normalizing for these differences, the MALS detector results could be nonsensical and improperly weighted toward different detector angles.

### Electrophoretic Light Scattering

Electrophoretic light scattering (ELS) is a technique used to measure the electrophoretic mobility of particles in dispersion, or molecules in solution. This mobility is often converted to Zeta potential to enable comparison of materials under different experimental conditions. The fundamental physical principle is that of electrophoresis. A dispersion is introduced into a cell containing two electrodes. An electrical field is applied to the electrodes, and particles or molecules that have a net charge, or more strictly a net zeta potential will migrate towards the oppositely charged electrode with a velocity, known as the mobility, that is related to their zeta potential.

When an electric field is applied to a sample, any charged objects in the sample will be influenced by that field. The extra movement that particles exhibit as a result of them experiencing the electric field is called the electrophoretic mobility. Its typical units are μm·cm/V·s (micrometer centimeter per Volt second) since it is a velocity [μm/s] per field strength [V/cm]. The electrophoretic mobility is the direct measurement from which the zeta potential can be derived (using either the Smoluchowski/Debye-Hückel approximations or the complete Henry function F(κa) to get from the mobility to a zeta potential).

### Electronics

### Transistor

A transistor is a type of semiconductor device that can be used to conduct and insulate electric current or voltage. A transistor acts as a switch and an amplifier, and is a miniature device that is used to control or regulate the flow of electronic signals. There are mainly two types of transistors, based on how they are used in a circuit: bipolar junction transistors (BJTs) and field effect transistors (FETs).

### Bipolar Junction Transistor (BJT)

The three terminals of BJT are the base, emitter and collector. A very small current flowing between the base and emitter can control a larger flow of current between the collector and emitter terminal. There are two types of BJT, a P-N-P transistor and a N-P-N transistor.

### Field Effect Transistor (FET)

For a FET, the three terminals are Gate, Source and Drain. The voltage at the gate terminal can control a current between the source and the drain. A FET is a unipolar transistor in which N-channel FET or P-channel FET are used for conduction. The main applications of FETs are in low noise amplifiers, buffer amplifiers and analogue switches.

### Metal-Oxide-Semiconductor Field-Effect Transistor (MOSFET)

A metal-oxide-semiconductor field-effect transistor (MOSFET) is a field-effect transistor (FET with an insulated gate) where the voltage determines the conductivity of the device. It is used for switching or amplifying signals. The ability to change conductivity with the amount of applied voltage can be used for amplifying or switching electronic signals.

The silicon dioxide forms the Gate of the MOSFET. It is used to provide isolation by preventing the direct flow of charges on the gate to the conducting channel. Since they can be made with either p-type or n-type semiconductors, complementary pairs of MOSFETs can be used to make switching circuits with very low power consumption, in the form of CMOS logic. MOSFETs are particularly useful in amplifiers due to their input impedance being nearly infinite which allows the amplifier to capture almost all the incoming signal. The main advantage is that it requires almost no input current to control the load current and that's why we choose MOSFET over BJT.

An n-channel MOSFET has a drain and a source that are heavily doped N+ region and the substrate is p-type. The current flows due to the flow of negatively charged. When we apply the positive gate voltage, the holes present beneath the oxide layer experience repulsive force and the holes are pushed downwards into the bound negative charges which are associated with the acceptor atoms. The positive gate voltage also attracts electrons from the N+ source and drain region into the channel thus an electron reach channel is formed.

### Voltage Regulator

A voltage regulator generates a fixed output voltage of a preset magnitude that remains constant regardless of changes to its input voltage or load conditions. There are two types of voltage regulators: linear and switching. A linear regulator employs an active (BJT or MOSFET) pass device (series or shunt) controlled by a high gain differential amplifier. It compares the output voltage with a precise reference voltage and adjusts the pass device to maintain a constant output voltage. A switching regulator converts the dc input voltage to a switched voltage applied to a power MOSFET or BJT switch. The filtered power switch output voltage is fed back to a circuit that controls the power switch on and off times so that the output voltage remains constant regardless of input voltage or load current changes.

### Operational Amplifier

An operational amplifier (op-amp) is an integrated circuit (IC) that amplifies the difference in voltage between two inputs, and can be configured to perform arithmetic operations. An op-amp has five terminals: positive power supply, negative power supply (GND), noninverting input, inverting input, and output. An op-amp amplifies the difference in voltage between its noninverting (IN(+)) and inverting (IN(−)) inputs.

An op-amp may act as a voltage amplifier or a comparator. Op-amps are generally used with negative feedback to reduce product variations in gain and expand the bandwidth. Typical applications of op-amps include noninverting amplifiers, inverting amplifiers, and voltage followers.

### Current Technologies

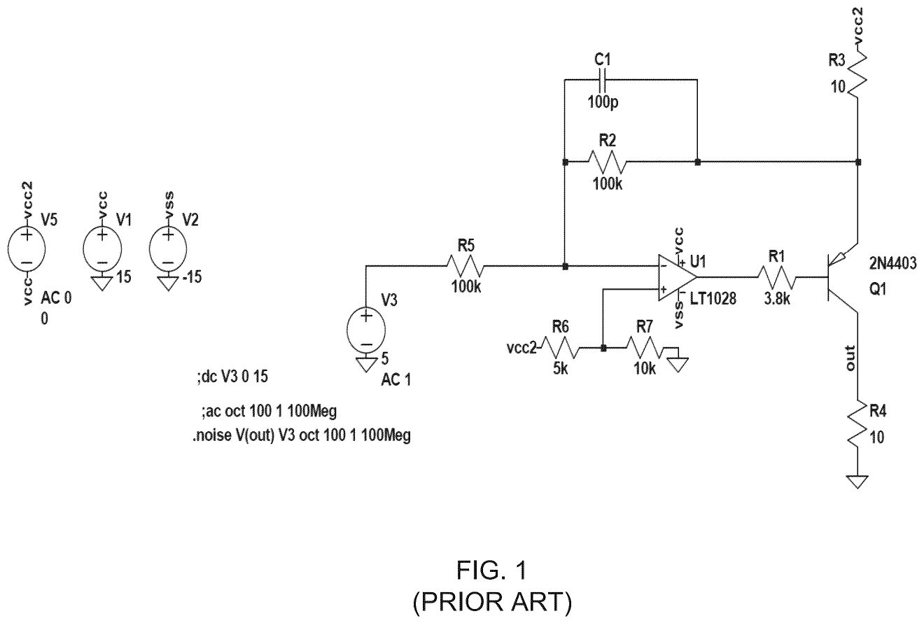

Current laser drivers include a constant-current circuit, as depicted in FIG. 1. Such a constant-current circuit has little rejection of power supply noise, where the noise would have to be cancelled out via voltage regulators that low performance at and above 100 kHz (the range for light scattering measurements.

Laser drivers using such a constant-current circuit exhibit problems for light scattering measurements. Namely, such laser drivers exhibit noise or instability at frequencies between 8 kHz to 100 kHz as artifacts, which result in incorrect particle size measurements. The noise/instability could be caused by (a) noise on the power supply coupling through to the laser, (b) gain peaking at the top of the constant-power control loop, and/or (c) instability in the presence of laser mode hops.

Current limits in laser driver circuits are intended to ensure that the laser is never operated outside of its design parameters, even if the laser monitor is not present. Current laser drivers are tuned specifically to the characteristics of the drive transistor, specifically, the beta value. The beta values may not be well controlled by transistor vendors, and could change between parts or even as a function of temperature. In addition, current laser driver circuits have a form of a clamp circuit that directly affects the input of its transistor and is highly sensitive to the device properties of the transistor.

Thus, there is a need for a laser driver circuit for measuring electrophoretic mobility of a sample.

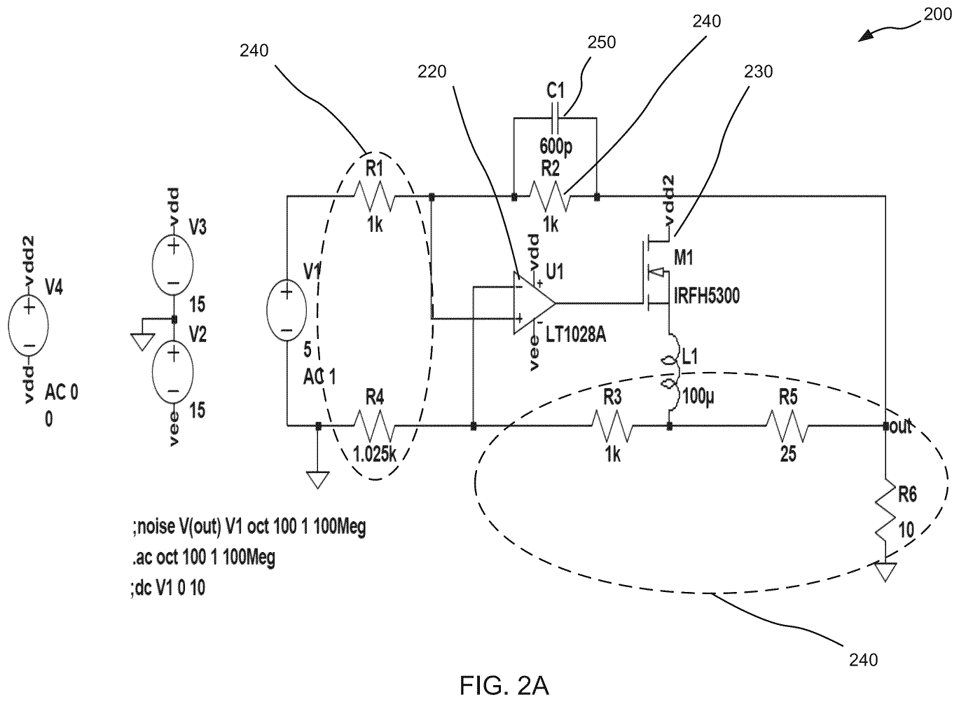

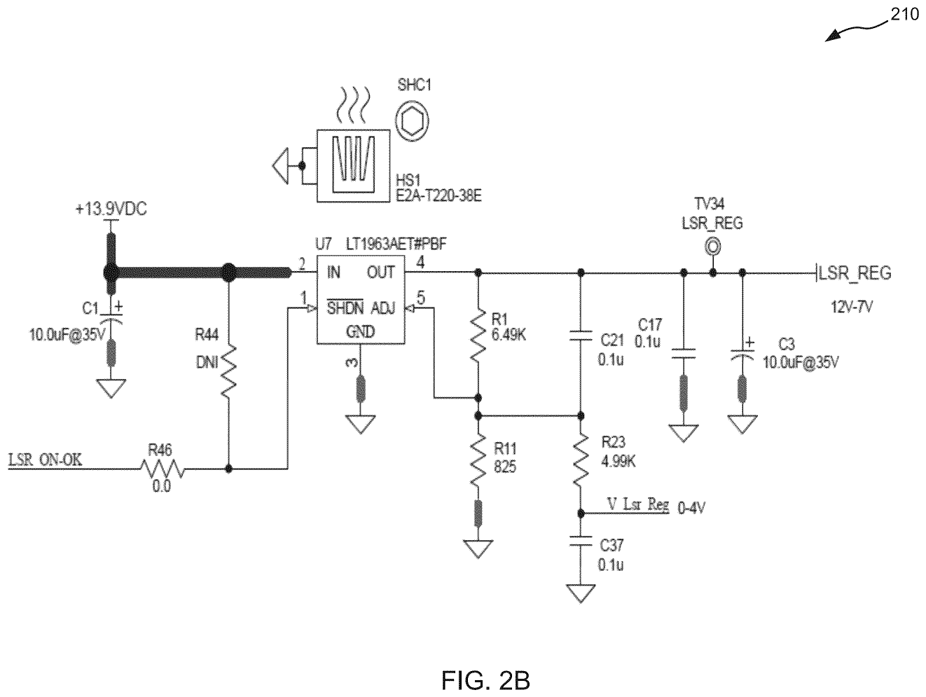

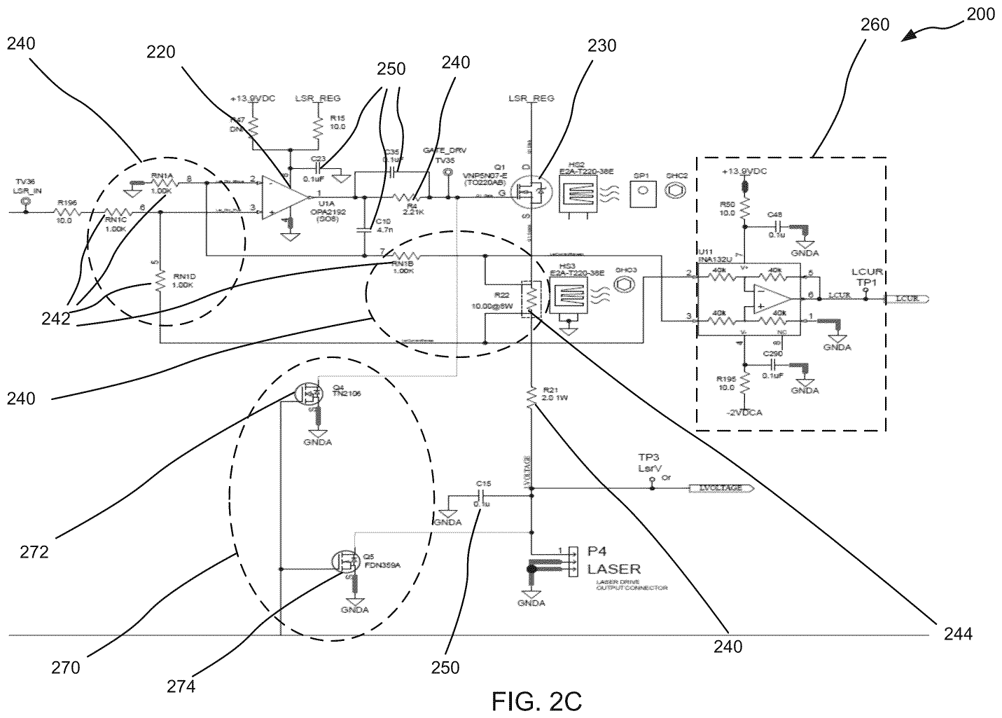

Referring to FIG. 2A, FIG. 2B, and FIG. 2C, in an exemplary embodiment, the circuit includes (1) a voltage regulator circuit 210 to receive an input voltage and to output a stable output voltage, (2) an operational amplifier 220 electrically coupled to an output of voltage regulator circuit 210, (3) a transistor 230 electrically coupled to an output of operational amplifier 220 and to the output of voltage regulator circuit 210, (4) a plurality of resistors 240 electrically coupled to operational amplifier 220 and to transistor 230, (5) a plurality of capacitors 250 electrically coupled to operational amplifier 220, to transistor 230, and to plurality of resistors 240, and (6) where operational amplifier 220 is to output a voltage to adjust a gate voltage of transistor 230 such that a drain source resistance of transistor 230 allows a controlled current to flow to a laser (e.g., via P4 LASER in FIG. 2C) for measuring electrophoretic mobility of a sample. In an embodiment, the lower capacitance of transistor 230, as compared to a BJT, leads to higher bandwidth for the laser driver circuit. In addition, for example, transistor 230 has low leakage current. In an embodiment, operational amplifier 220 references a control input (e.g., voltage at TV36 in FIG. 2C) to a ground voltage (GND) and make a differential measurement of a current sense resistor (e.g., R22 in FIG. 2C), allowing operational amplifier 220 to use feedback to actively cancel noise in the power supply in a stable way (instead of referencing a positive power rail as in current technologies).

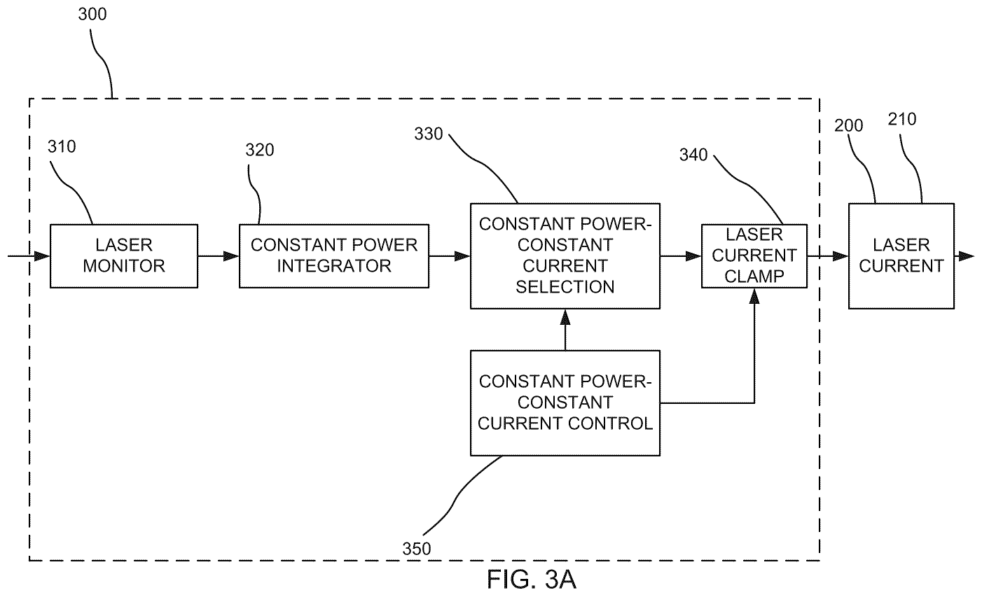

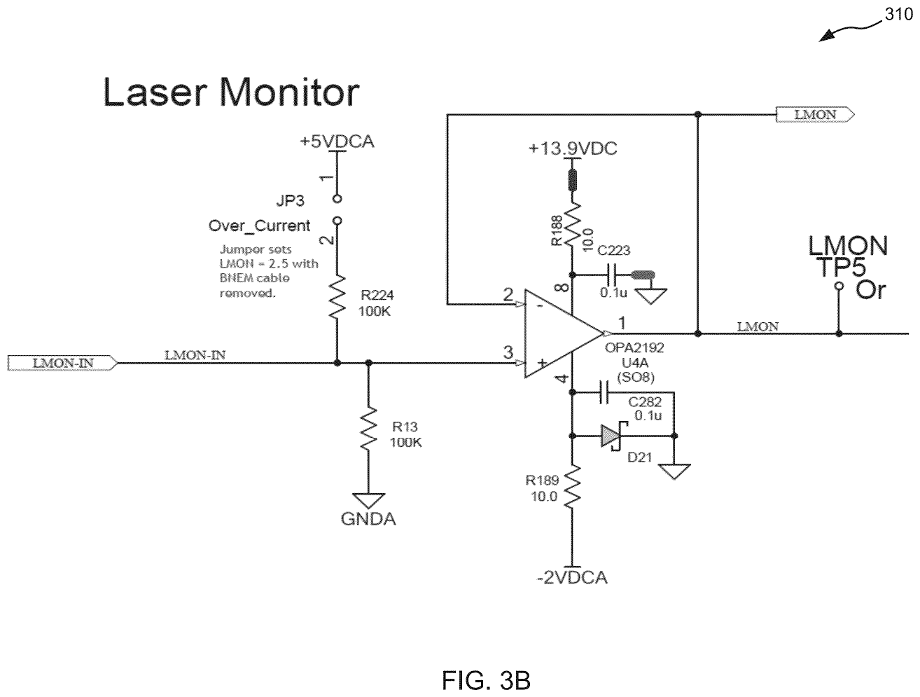

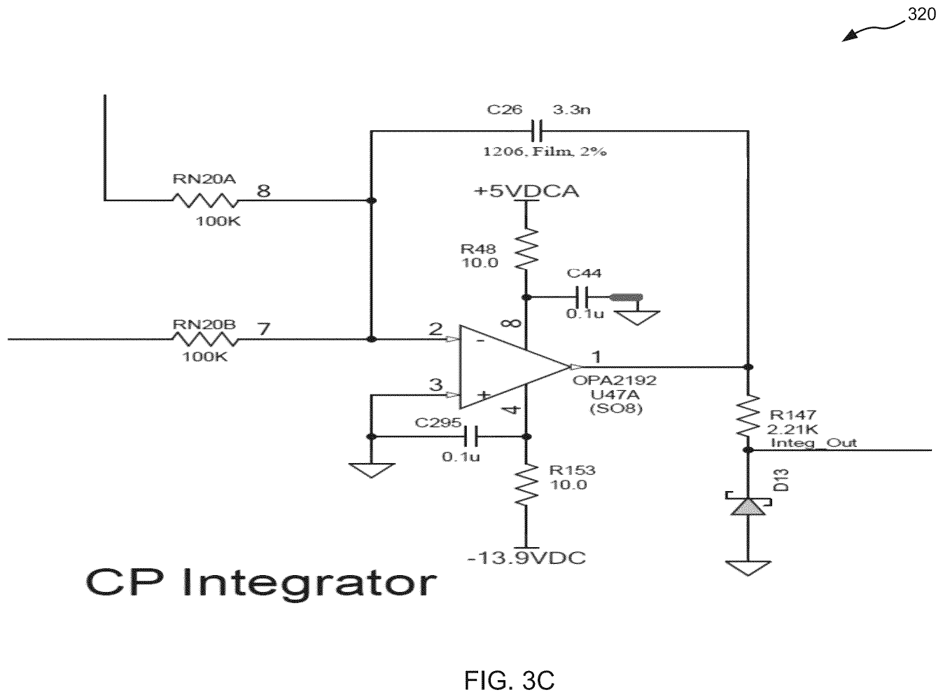

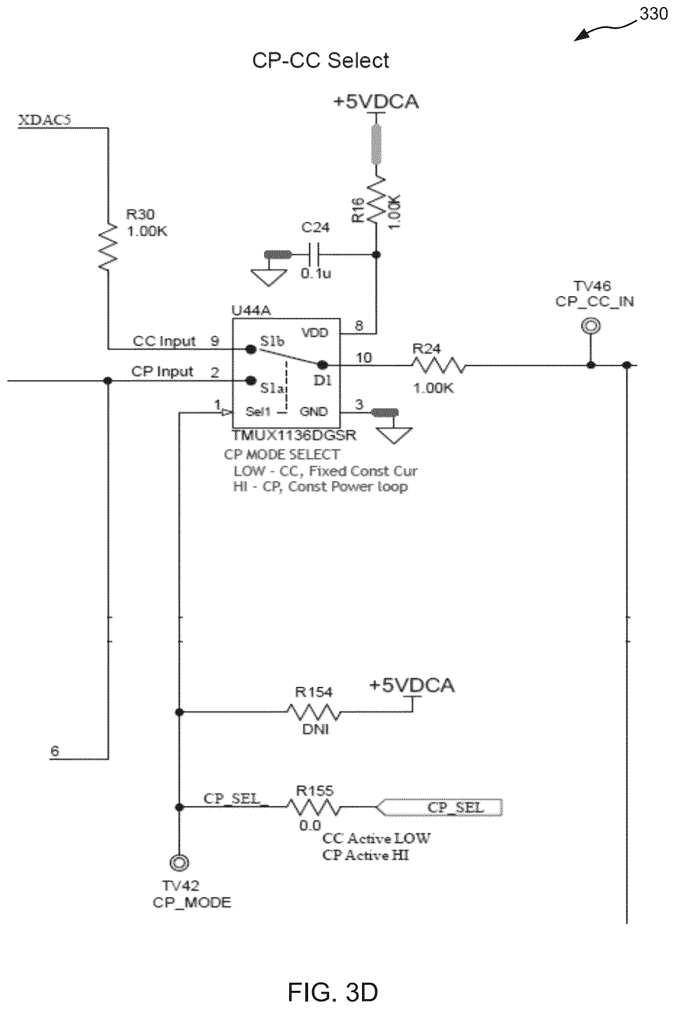

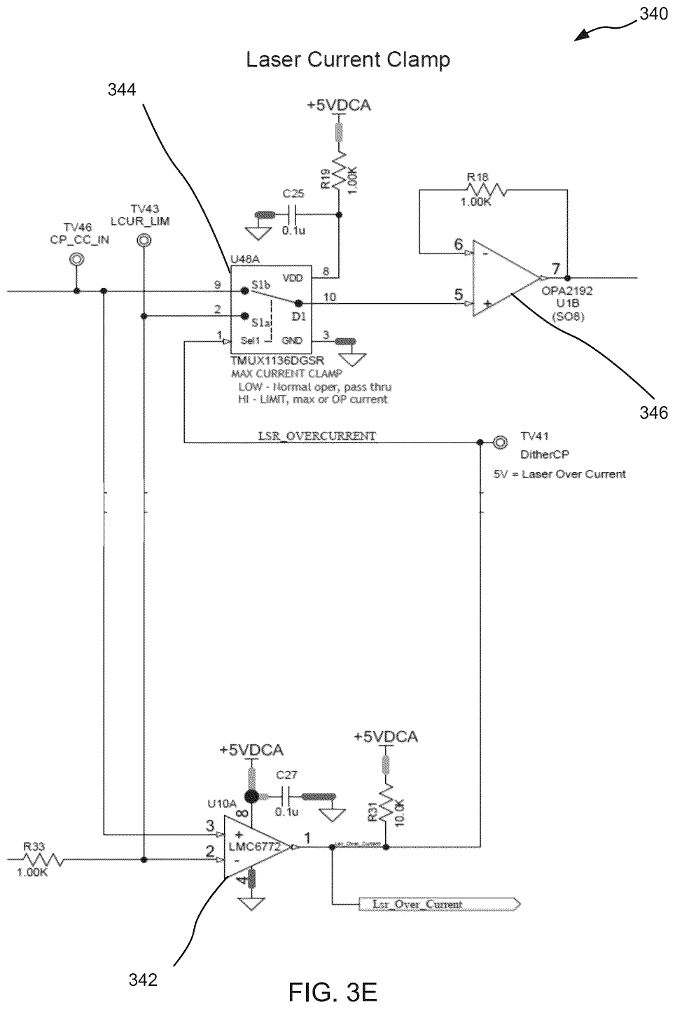

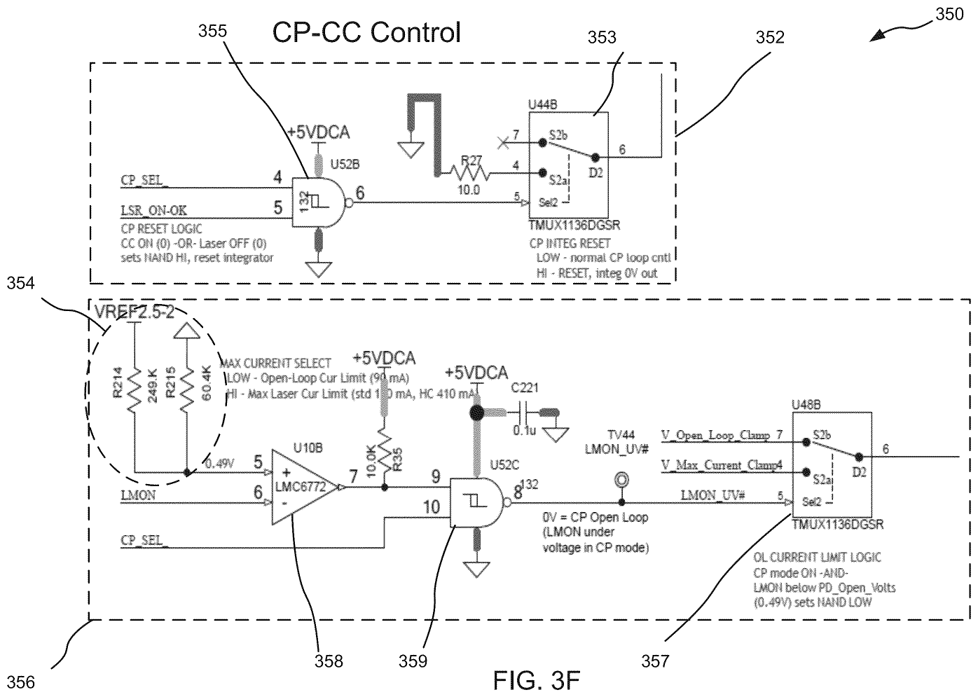

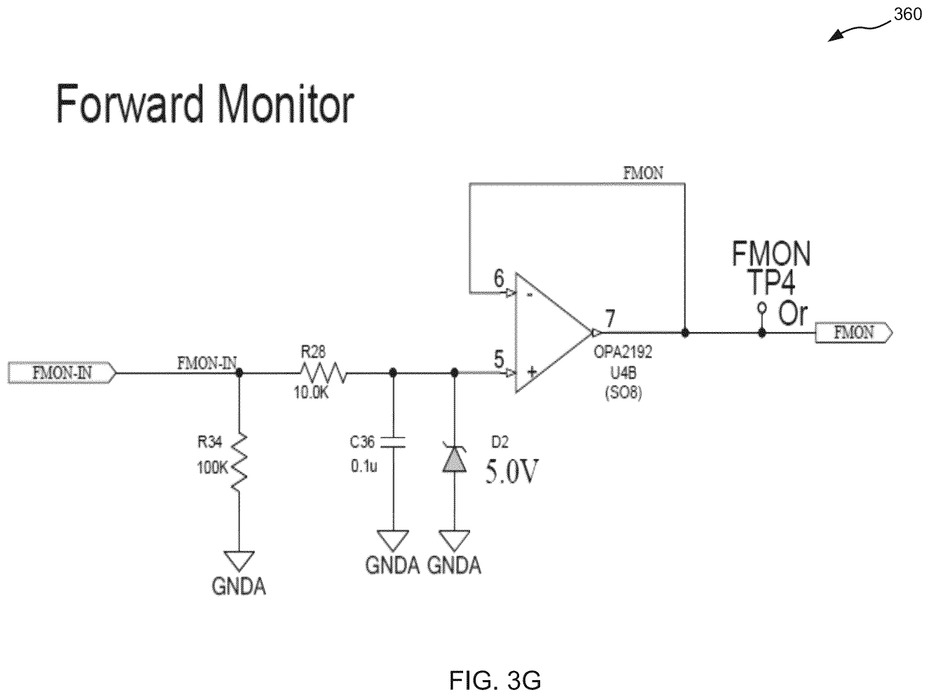

Referring to FIG. 3A, FIG. 3B, FIG. 3C, and FIG. 3D, in an exemplary embodiment, the circuit includes (1) a laser monitor circuit 310 to generate a laser monitor output voltage indicating an amount of optical power being generated by a laser for measuring electrophoretic mobility of a sample, (2) a constant power integrator circuit 320 (CP Integrator) electrically coupled to an output of laser monitor circuit 310 and configured to determine an amount of current required to maintain a particular laser optical output power for the laser, and (3) a constant power-constant current selection circuit 330 (CP-CC Select) electrically coupled to an output of constant power integrator circuit 320, where constant power-constant current selection circuit 330 is to output a selected current for a laser current circuit to flow controlled current to the laser. In an embodiment, constant power-constant current selection circuit 320 is, in response to a first selection signal corresponding to a first command (e.g., CP Input 2), to set an output of constant power integrator circuit 320 (i.e., constant POWER) as the selected current (operating in a closed loop configuration with the laser monitor circuit), and where constant power-constant current selection circuit 330 is, in response to a second selection signal corresponding to a second command (e.g., CC Input 9), to couple a programmable voltage source to set the selected current (i.e., directly set) (i.e., constant CURRENT).

### Matched Resistor Network

In an embodiment, as depicted in FIG. 2C, plurality of resistors 240 includes a matched resistor network 242. In an embodiment, matched resistor network 242 includes matched resistors having equal resistance values in the range of 1 kOhm to 10 kOhm. In an embodiment, each of the matched resistors has a value of 1 kOhm. In an embodiment, plurality of resistors 240 includes a current sense resistor 244, where operational amplifier 220 is to reference a control input voltage (e.g., TV36) to a ground voltage (GND) to make a differential measurement of current sense resistor 244, thereby cancelling noise in the current sent to the laser.

### Current Sense and Safety Circuits

As shown in FIG. 2C, in a further embodiment, the laser driver circuit further includes a current sense circuit 260 to measure the current sent to the laser via operational amplifier 220. In a further embodiment, as depicted in FIG. 2C, the laser driver circuit further includes a safety circuit 270 to limit the current flowing to the laser, thereby avoiding overdriving the laser, where safety circuit 270 includes at least two transistors 272, 274 electrically coupled to plurality of resistors 240 and to plurality of capacitors 250. In an embodiment, at least two transistors 272, 274 include n-channel MOSFETs. For example, at least two transistors 272, 274 are n-channel MOSFETs. Current sense circuit 260 and safety circuit 270 could prevent overdriving the laser.

### Forward Monitor

Referring to FIG. 3G, the laser driver circuit further includes a forward monitor circuit 360 to ensure that laser light is passing through an entire optical path of an instrument to measure the electrophoretic mobility of the sample (i.e., detect if there is a bubble in flow cell/cuvette-interrupts optical path).

### Laser Current Clamp

Referring to FIG. 3A and FIG. 3E, the laser driver circuit further includes a laser current clamp circuit 340 to ensure that the selected current is not driven beyond a maximum rated current of the laser. Laser current claim circuit 340 allows for setting a limiting current identically for each board of the laser driver, independent of any specific component properties of transistors in the laser driver. In an embodiment, laser current clamp circuit 340 includes (a) a comparator 342 to detect over current in the selected current, (b) a multiplexer 344 (MUX) to switch to a clamped (i.e., safe) voltage (e.g., U10A pin 2 voltage in FIG. 3E) in response to detecting the over current (e.g., pin 1 in FIG. 3E) (i.e., to protect the laser), and (c) an operational amplifier 346 (e.g., an impedance buffer) to output a clamped current corresponding to the clamped voltage to the laser current circuit in response to the detecting the over current and to output the selected current in response to multiplexer 344 not detecting the over current. For example, in order to limit current to the laser to 200 mA, the current limit is set to 2V such that if the selected current is over 2 V, the comparator would detect an overvoltage/over current situation.

### Constant Power-Constant Current Control

Referring to FIG. 3A and FIG. 3f, the laser driver circuit further includes a constant power-constant current control circuit 350 (CP-CC Control) to set limits of laser current clamp circuit 340 based on at least one electrical fault signal and to clamp an output voltage of constant power integrator circuit 320 to reset constant power integrator circuit 320 to avoid the output voltage of constant power integrator circuit 320 from reaching rail voltages. In an embodiment, constant power-constant current control circuit 350 includes (a) an integrator reset circuit 352 including (i) an integrator reset multiplexer 353, and (ii) an integrator reset logic 355 electrically coupled to an input of integrator reset multiplexer 353, where the integrator reset logic 355 is, in response to a third selection signal being high (e.g., CP SEL), to enable operation of constant power integrator circuit 320 by outputting the first selection signal corresponding to the first command, and (b) a clamp circuit voltage selector circuit 356 including (i) a voltage selector multiplexer 357, (ii) a comparator 358 to compare a laser monitor output voltage of laser monitor circuit 310 to an output voltage of a voltage divider circuit 354 and to output a comparator signal, (ii) a voltage selector logic 359 electrically coupled to an output of comparator 358 and electrically coupled to an input of voltage selector multiplexer 357, where voltage selector logic 359 is, in response to a fourth selection signal being high (e.g., CP SEL) and in response to a value of the comparator signal, to select one of two electrical fault conditions (e.g., V Open Loop Clamp pin 7 and V Max Current Clamp pin 4), thereby outputting the at least one electrical fault signal to constant power-constant current control circuit 350. For example, comparator 358 compares laser power LMON to voltage divider 354 on pin 5, such that if the it is lower than 0.49V, comparator 358 switches its output to open loop clamp voltage pin 7, thereby lowering the clamp voltage (e.g., by ˜50%) to prevent overdriving the laser when it is reconnected. In another example, if laser power LMON is above 0.49 V, comparator 358 switches output to V Max Current Clamp pin 4, thereby setting laser current clamp circuit 340 to normal closed loop (servo circuit) constant power operation.

### Example

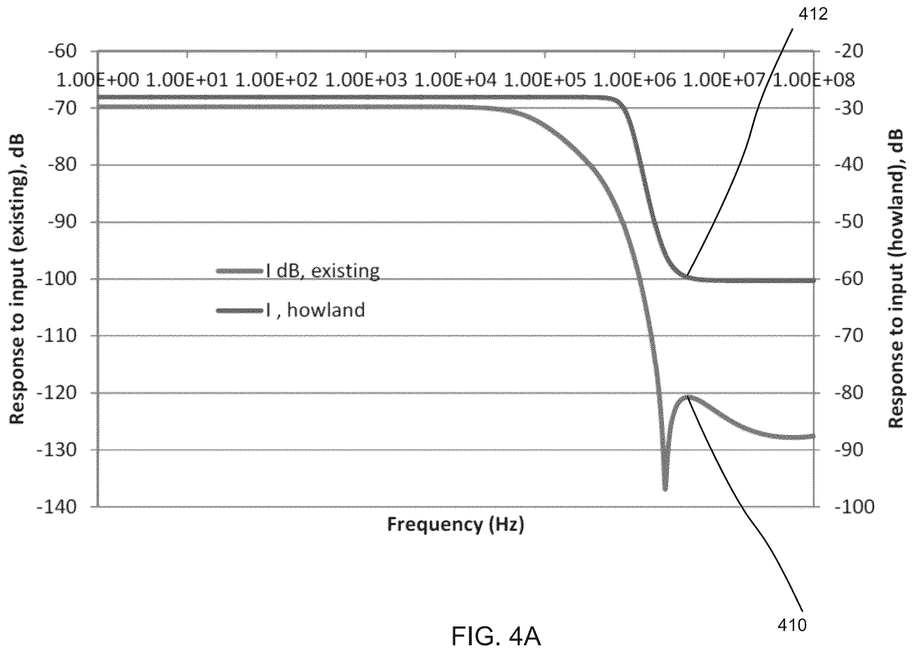

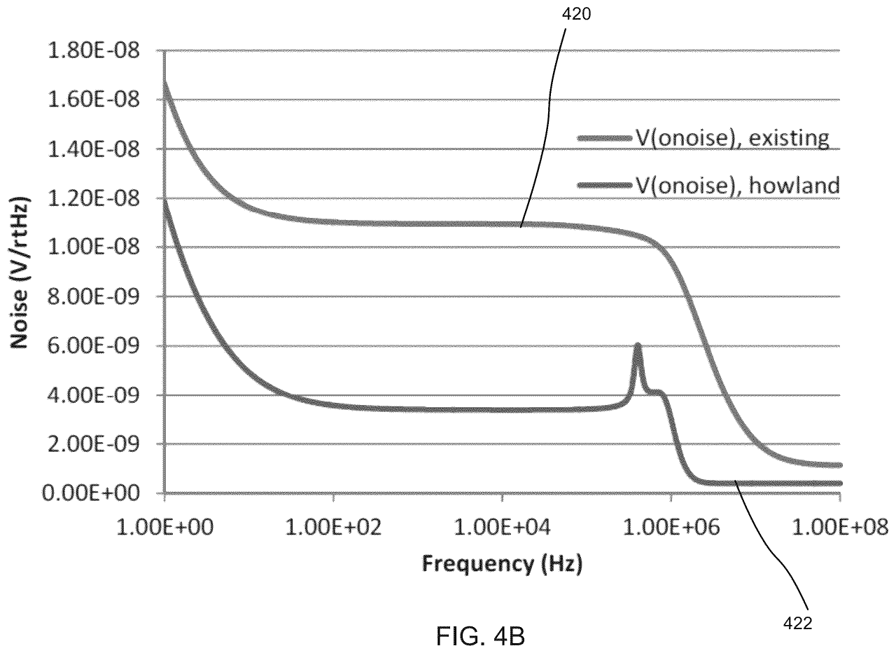

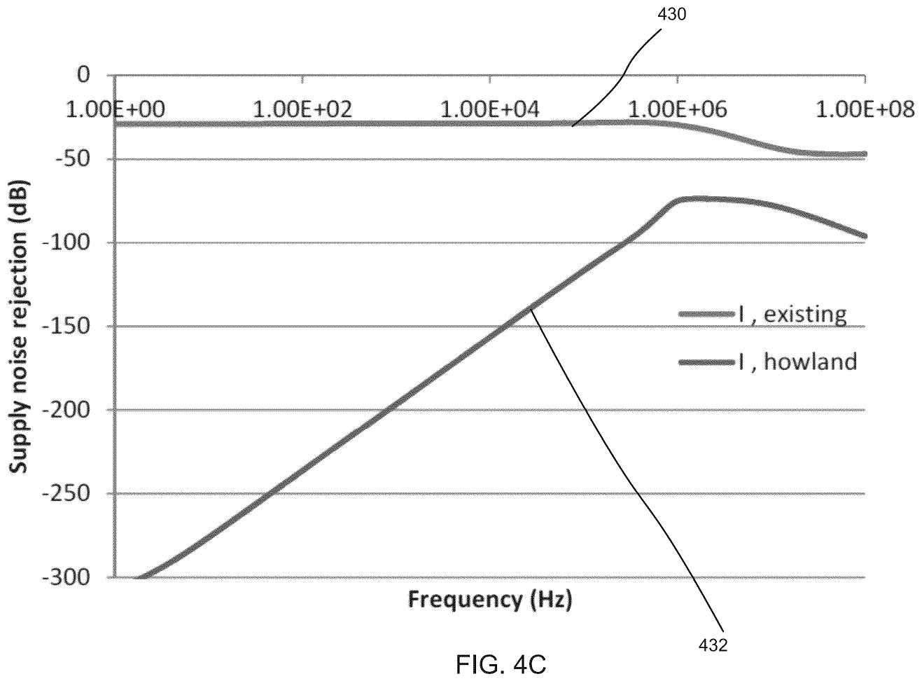

For example, FIG. 4A depicts the high frequency response 412 of the laser driver of the present disclosure (>500 kHz) compared to the high frequency response 410 of current technologies (30 kHz). The use of an n-channel MOSFET in the laser drive of the present disclosure rather than a p-channel BJT of current technologies allows for the laser driver of the present disclosure to have an improved high frequency response (higher bandwidth) as compared to current technologies. The higher bandwidth in the laser driver of the present disclosure allows for the active regulation of the laser drive current to higher frequencies, and hence lower total output noise over the bandwidth of interest, as compared to current technologies.

In addition, for example, FIG. 4B shows that the output noise 422 at all frequencies of the laser driver of the present disclosure is lower than the output noise 420 of current technologies. The use of low-value feedback resistors in the laser driver of the present disclosure reduces shot noise as compared to current technologies. In addition, the use of an n-channel MOSFET in the laser drive of the present disclosure rather than a p-channel BJT of current technologies also helps to reduce noise.

Also, for example, FIG. 4C depicts the supply noise rejection 432 of the laser driver of the present disclosure being better than the supply noise rejection 430 of current technologies. Current technologies use a conventional high-side op-amp current source, where the control signal and sense element are referenced to the positive supply rail, thereby leading to the power supply noise being easily coupled into the current drive. The laser driver of the present disclosure references the control input to ground (GND), and makes a differential measurement of the current sense resistor, thereby allowing the op-amp to use feedback to actively cancel noise in the power supply.

What is claimed is:

1. A laser driver circuit comprising:
a voltage regulator circuit to receive an input voltage and to output a stable output voltage;
an operational amplifier electrically coupled to an output of the voltage regulator circuit;
a transistor electrically coupled to an output of the operational amplifier and to the output of the voltage regulator circuit;
a plurality of resistors electrically coupled to the operational amplifier and to the transistor;
a plurality of capacitors electrically coupled to the operational amplifier, to the transistor, and to the plurality of resistors; and
wherein the operational amplifier is to output a voltage to adjust a gate voltage of the transistor such that a drain source resistance of the transistor allows a controlled current to flow to a laser for measuring electrophoretic mobility of a sample.

2. The circuit of claim 1 wherein the operational amplifier comprises a low noise, precision operational amplifier with a low offset.

3. The circuit of claim 1 wherein the transistor comprises a n-channel MOSFET.

4. The circuit of claim 1 wherein the plurality of resistors comprises a matched resistor network.

5. The circuit of claim 4 wherein the matched resistor network comprises matched resistors having equal resistance values in the range of 1 kOhm to 10 kOhm.

6. The circuit of claim 5 wherein each of the matched resistors has a value of 1 kOhm.

7. The circuit of claim 1 wherein the plurality of resistors comprises a current sense resistor, wherein the operational amplifier is to reference a control input voltage to a ground voltage to make a differential measurement of the current sense resistor, thereby cancelling noise in the current sent to the laser.

8. The circuit of claim 1 further comprising a current sense circuit to measure the current sent to the laser via the operational amplifier.

9. The circuit of claim 1 further comprising a safety circuit to limit the current flowing to the laser, thereby avoiding overdriving the laser,
wherein the safety circuit comprises at least two transistors electrically coupled to the plurality of resistors and to the plurality of capacitors.

10. The circuit of claim 9 wherein the at least two transistors comprise n-channel MOSFETs.

11. A laser driver circuit comprising:
a laser monitor circuit to generate a laser monitor output voltage indicating an amount of optical power being generated by a laser for measuring electrophoretic mobility of a sample;
a constant power integrator circuit electrically coupled to an output of the laser monitor circuit and configured to determine an amount of current required to maintain a particular laser optical output power for the laser; and
a constant power-constant current selection circuit electrically coupled to an output of the constant power integrator circuit,
wherein the constant power-constant current selection circuit is to output a selected current for a laser current circuit to flow controlled current to the laser.

12. The circuit of claim 11
wherein the constant power-constant current selection circuit is, in response to a first selection signal corresponding to a first command, to set an output of the constant power integrator circuit as the selected current, and
wherein the constant power-constant current selection circuit is, in response to a second selection signal corresponding to a second command, to couple a programmable voltage source to set the selected current.

13. The circuit of claim 11 further comprising a forward monitor circuit to ensure that laser light is passing through an entire optical path of an instrument to measure the electrophoretic mobility of the sample.

14. The circuit of claim 11 further comprising a laser current clamp circuit to ensure that the selected current is not driven beyond a maximum rated current of the laser.

15. The circuit of claim 14 wherein the laser current clamp circuit comprises:
a comparator to detect over current in the selected current;
a multiplexer to switch to a clamped voltage in response to detecting the over current; and
an operational amplifier to output a clamped current corresponding to the clamped voltage to the laser current circuit in response to the detecting the over current and to output the selected current in response to the multiplexer not detecting the over current.

16. The circuit of claim 14 further comprising a constant power-constant current control circuit to set limits of the laser current clamp circuit based on at least one electrical fault signal and to clamp an output voltage of the constant power integrator circuit to reset the constant power integrator circuit to avoid the output voltage of the constant power integrator circuit from reaching rail voltages.

17. The circuit of claim 16 wherein the constant power-constant current control circuit comprises:
an integrator reset circuit comprising
an integrator reset multiplexer, and
an integrator reset logic electrically coupled to an input of the integrator reset multiplexer,
wherein the integrator reset logic is, in response to a third selection signal being high, to enable operation of the constant power integrator circuit by outputting the first selection signal corresponding to the first command; and
a clamp circuit voltage selector circuit comprising
a voltage selector multiplexer,
a comparator to compare a laser monitor output voltage of the laser monitor circuit to an output voltage of a voltage divider circuit and to output a comparator signal,
a voltage selector logic electrically coupled to an output of the comparator and electrically coupled to an input of the voltage selector multiplexer,
wherein the voltage selector logic is, in response to a fourth selection signal being high and in response to a value of the comparator signal, to select one of two electrical fault conditions, thereby outputting the at least one electrical fault signal to the constant power-constant current control circuit.
